(19) United States
(12) Patent Application Publication
(10) Pub. No.: US 2013/0071618 A1
(43) Pub. Date: Mar. 21, 2013

(54) Thin Film, Pattern Layer, And Manufacturing Method Thereof

(71) Applicant: Wen-da Cheng, Guangdong (CN)

(72) Inventor: Wen-da Cheng, Guangdong (CN)

(73) Assignee: Shenzhen China Star Optoelectronics Technology Co. LTD., Shenzhen City, Guangdong (CN)

(21) Appl. No.: 13/379,350

(22) PCT Filed: Oct. 18, 2011
(86) PCT No.: PCT/CN11/80939

§ 371 Date: Dec. 19, 2011

(30) Foreign Application Priority Data
Sep. 20, 2011 (CN) 2011102800281

(51) Int. Cl. B32B 5/16; H01L 21/302

(52) U.S. Cl. 428/143; 438/694; 257/E21.214

(57) ABSTRACT

The present invention provides a pattern layer and a manufacturing method thereof. The manufacturing method of the pattern layer includes: performing coating on the substrate and at the same time, controlling coating parameter to vary with time so as to form a thin film of which film quality varies with coated film thickness on the substrate; and performing etching on the thin film so as to have lateral etch rate of the thin film changing with the film quality to thereby form the pattern layer having a side surface of a predetermined curvature. The present invention also provides a thin film. With the above-discussed method, the lateral etch rate of the thin film can be controlled through change of film quality.

### BACKGROUND OF THE INVENTION

1. Field of the Invention

The present invention relates to the field of semiconductor manufacturing, and in particular to a thin film, pattern layer, and manufacturing method thereof.

2. The Related Arts

In the manufacturing techniques of liquid crystal panels or other semiconductors, it needs to form various pattern layers, such as wirings including scan lines and data lines, on a substrate. The structural features of the pattern layers have a significant influence on the subsequent operations. In the process of manufacturing a pattern layer through coating and etching, it often needs to control side surface curvature of the pattern layer. In the conventional technology, coating is generally performed with fixed coating parameters and this leads to a uniform quality of the film in a thickness direction, which makes lateral etch rate constant along the thickness direction. Thus, in the process of subjecting a coated film to etching for forming a patter layer, controlling the side surface curvature is often effected by changing etching solution, etching facility, and etching techniques.

The conventionally used technology will be described as follows with reference to FIGS. 1-2, which show schematic cross-sectional views of a pattern layer.

Referring to FIG. 1, since coating is carried out with fixed coating parameters, the film quality and the lateral etch rate of a coated film are constant in the thickness direction. Thus, a pattern layer 10 that is formed through etching has a side surface 11 that is of a relatively small curvature. Referring to FIG. 2, since the curvature of the side surface 11 is relatively small, this makes a thin film 13 that is formed in a next manufacturing process showing poor covering over the pattern layer 10. Further, gaps 12 are formed at sides of the pattern layer 10, and this affects the result of film coating and reduces yield rate of product.

Thus, it is desired to have a thin film, pattern layer, and manufacturing method thereof to overcome the above problems.

### SUMMARY OF THE INVENTION

The technical issue to be addressed by the present invention is to provide a thin film, pattern layer, and manufacturing method thereof, which controls lateral etch rate of a thin film through varying film quality.

To address the technical issue, the present invention adopts a technical solution that provides a manufacturing method of pattern layer, which comprises performing film coating on a substrate and at the same time, controlling coating parameters to vary with time so as to form a thin film of which film quality varies with coated film thickness on the substrate; and performing etching on the thin film so as to have lateral etch rate of the thin film changing with the film quality to thereby form a pattern layer having a side surface of a predetermined curvature.

Wherein, the thin film contains crystal grains of which sizes get smaller with the coated film thickness in a direction away from the substrate.

Wherein, the coating parameters comprise substrate temperature, gas pressure around substrate, sputtering power, or biasing voltage between substrate and target.

Wherein, in the step of performing coating on a substrate and at the same time controlling coating parameters to vary with time, the substrate temperature is controlled to get gradually lowering with time.

Wherein, in the step of performing coating on a substrate and at the same time controlling coating parameters to vary with time, the sputtering power is controlled to get gradually lowering with time.

Wherein, in the step of performing coating on a substrate and at the same time controlling coating parameters to vary with time, the biasing voltage between the substrate and the target is controlled to get gradually lowering with time.

Wherein, in the step of performing coating on a substrate and at the same time controlling coating parameters to vary with time, the gas pressure around the substrate is controlled to get gradually increasing with time.

Wherein, the predetermined curvature is in a range of 30-40 degrees.

To address the above discussed technical issue, the present invention adopts another technical solution, which provides a thin film. The thin film is formed on a substrate and the thin film comprises crystal grains having sizes getting gradually smaller with coated film thickness in a direction away from the substrate.

Wherein, the thin film has lateral etch rate that gets smaller with the sizes of the crystal grains getting larger.

Wherein, the thin film is subjected to etching to form a pattern layer having a side surface of a predetermined curvature.

Wherein, the predetermined curvature is within a range of 30-40 degrees.

To address the above discussed technical issue, the present invention adopts another technical solution, which provides a pattern layer. The pattern layer is formed on a substrate and the pattern layer comprises crystal grains having sizes getting gradually smaller with coated film thickness in a direction away from the substrate.

Wherein, the pattern layer has lateral etch rate that gets smaller with the sizes of the crystal grains getting larger.

Wherein, the pattern layer has a side surface having a predetermined curvature.

Wherein, the predetermined curvature is in a range of 30-40 degrees.

The efficacy of the present invention is that to be distinguish from the state of the art, the present invention provides the thin film, the pattern layer and the manufacturing method thereof, which apply variation of the film quality to control the lateral etch rate of the thin film. In addition, the problem of small side surface curvature of the pattern layer is improved and abnormality of film coating of product is reduced, so that the yield rate of the subsequent operation can be increased.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIGS. 1-2 are schematic cross-sectional views showing a pattern layer according to the conventional technology;

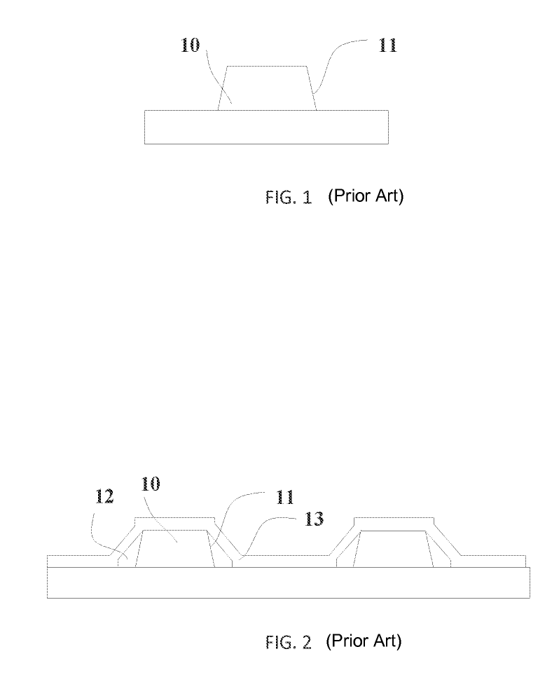

FIG. 3 is a schematic view illustrating structure of a thin film according to a preferred embodiment of the present invention;

FIGS. 4-5 are schematic cross-sectional views showing a pattern layer formed through etching the thin film of FIG. 3; and

FIG. 6 is a flow chart of a manufacturing method for the pattern layer shown in FIGS. 4-5.

### DETAILED DESCRIPTION OF THE PREFERRED EMBODIMENTS

The present invention will be descried in detail with reference to embodiments and drawings thereof.

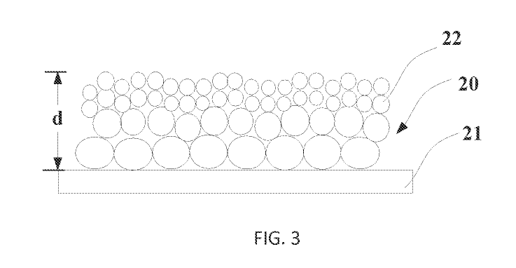

Referring to FIG. 3, FIG. 3 is a schematic view illustrating structure of a thin film according to a preferred embodiment of the present invention. As shown in FIG. 3, the thin film 20 of the present invention is formed on a substrate 21. Preferably, the thin film 20 is made of a single material. Film quality of the thin film 20 is made varying with the coated film thickness. Specifically, the thin film 20 contains crystal grains 22 of variable sizes. The size of the crystal grains 22 gets smaller with the coated film thickness d in a direction away from the substrate 21. The closer the crystal grains 22 are to the substrate 21, the larger the size is and the more distant the crystal grains 22 are from the substrate 21, the smaller the size is. Since the size of the crystal grains 22 affects the lateral etch rate of the thin film 20, the lateral etch rate gets larger when the size of the crystal grains 22 becomes smaller and the lateral etch rate gets smaller when the size of the crystal grains 22 becomes larger. As a consequence, the lateral etch rate of the thin film 20 varies with the coated film thickness d.

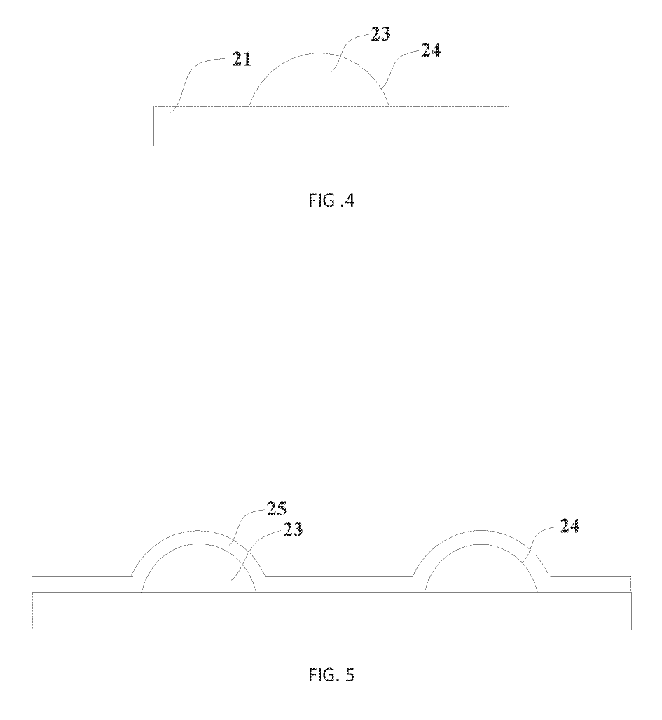

FIG. 4 is a schematic cross-sectional view of a pattern layer formed through etching the thin film of FIG. 3. A s shown in FIGS. 3-4, since the lateral etch rate of the thin film 20 is affected by the size of the crystal grains 22, the size of the crystal grains 22 gets larger when they are closer to the substrate 21 and the lateral etch rate thereof is smaller, the size of the crystal grains 22 gets smaller when they are more distant from the substrate 21 and the lateral etch rate thereof is larger. Thus, the pattern layer 23 formed by etching the thin film 20 has a side surface 24 that has a relatively large curvature. The curvature of the side surface 24 is preferably in a range of 30-40 degrees.

Referring to FIG. 5, since the curvature of the side surface 24 is relatively large, a thin film 25 formed in a subsequent manufacturing process may have improved covering over the pattern layer 23 without causing any gap on sides of the pattern layer 23, so that abnormal coated film of product can be reduced and the yield rate of the subsequent operations is improved.

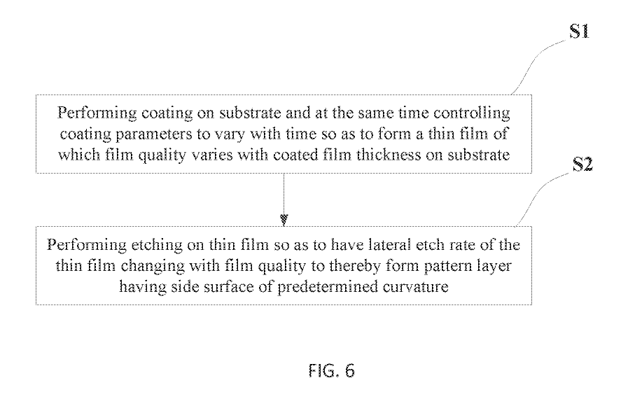

FIG. 6 is a flow chart of a manufacturing method for the pattern layer shown in FIGS. 4-5. As shown in FIG. 6, the manufacturing method for the pattern layer comprises the following steps:

S1: performing coating on a substrate and at the same time, controlling coating parameters to vary with time, so as to form a thin film of which film quality varies with coated film thickness on the substrate. The thin film is preferably made of a single material. The thin film coated in this step shows the film quality that varies with the coated film thickness. Specifically, sizes of crystal grains of the thin film gets smaller with the coated film thickness in a direction away from the substrate.

In a coating process, a number of parameters affect the crystal grains in coating the film. These parameters primarily include substrate temperature, gas pressure around the substrate, sputtering power, or biasing voltage between the substrate and a target. Generally, the higher the substrate temperature, the smaller the gas pressure around the substrate, the larger the sputtering power, or the higher the biasing voltage between the substrate and the target, the larger the sizes of the crystal grains will be. Thus, in the instant embodiment, through controlling the substrate temperature, the sputtering power, the biasing voltage between the substrate and the target to get smaller with time or controlling the gas pressure around the substrate to get larger with time, the sizes of the crystal grains of the thin film can be controlled to get smaller with the coated film thickness in a direction away from the substrate.

For example, when physical vapor deposition technique is used, being varied with time, the substrate temperature is made gradually lowering from 850 degrees Celsius to 700 degrees Celsius and the sputtering power is gradually lowered from 83 KW to 77 KW. When chemical vapor deposition technique is used, being varied with time, the substrate temperature is mad gradually lowering from 280 degrees Celsius to 270 degrees Celsius or gradually lowering from 360 degrees Celsius to 340 degrees Celsius, the gas pressure around the substrate is gradually increased from 1000 mmtorr to 2000 mmtorr, and the sputtering power is gradually lowered from 20 KW to 6K.

Thus, the present invention adopts coating performed with coating parameters varying with time to have the film quality varying with the coated film thickness thereby gaining control of the lateral etch rate of the thin film and thus obtaining a pattern layer having a relatively large curvature of side surface. Particularly, besides using a single material to carry out coating, it is also feasible to use different materials for coating in order to control thin films of different materials to have different lateral etch rates.

S2: performing etching on the thin film so as to have the lateral etch rate of the thin film changing with the film quality to thereby form the pattern layer having a side surface of a predetermined curvature. Details of the pattern layer formed with the etching of this step can be referred to the pattern layer shown in FIGS. 4-5 and redundant description will be omitted here.

The present invention provides the thin film, the pattern layer, and the manufacturing method thereof apply variation of the film quality to control the lateral etch rate of the thin film. In addition, the problem of small side surface curvature of the pattern layer is improved and abnormality of film coating of product is reduced, so that the yield rate of the subsequent operation can be increased.

Embodiments of the present invention have been described, but not to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A manufacturing method of a pattern layer, wherein the manufacturing method of pattern layer comprises:
performing coating on a substrate and at the same time, controlling coating parameters to vary with time, so as to form a thin film of which film quality varies with coated film thickness on the substrate; and
performing etching on the thin film so as to have lateral etch rate of the thin film changing with the film quality to thereby form a pattern layer having a side surface of a predetermined curvature.

2. The manufacturing method of a pattern layer as claimed in claim 1, wherein the thin film contains crystal grains of which sizes get smaller with the coated film thickness in a direction away from the substrate.

3. The manufacturing method of a pattern layer as claimed in claim 1, wherein the coating parameters comprise substrate temperature, gas pressure around the substrate, sputtering power, or biasing voltage between the substrate and a target.

4. The manufacturing method of a pattern layer as claimed in claim 1, wherein in the step of performing coating on a substrate and at the same time controlling coating parameters to vary with time, substrate temperature is controlled to get gradually lowering with time.

5. The manufacturing method of a pattern layer as claimed in claim 1, wherein in the step of performing coating on a substrate and at the same controlling coating parameters to vary with time, sputtering power is controlled to get gradually lowering with time.

6. The manufacturing method of a pattern layer as claimed in claim 1, wherein in the step of performing coating on a substrate and at the same time controlling coating parameters to vary with time, biasing voltage between the substrate and a target is controlled to get gradually lowering with time.

7. The manufacturing method of a pattern layer as claimed in claim 1, wherein in the step of performing coating on a substrate and at the same time controlling coating parameters to vary with time, gas pressure around the substrate is controlled to get gradually increasing with time.

8. The manufacturing method of a pattern layer as claimed in claim 1, wherein the predetermined curvature is in a range of 30-40 degrees.

9. A thin film, wherein the thin film is formed on a substrate and the thin film comprises crystal grains having sizes getting gradually smaller with coated film thickness in a direction away from the substrate.

10. The thin film as claimed in claim 9, wherein the thin film has lateral etch rate that gets smaller with the sizes of the crystal grains getting larger.

11. The thin film as claimed in claim 10, wherein the thin film is subjected to etching to form a pattern layer having a side surface of a predetermined curvature.

12. The thin film as claimed in claim 11, wherein the predetermined curvature is in a range of 30-40 degrees.

13. A pattern layer, wherein the pattern layer is formed on a substrate and the pattern layer comprises crystal grains having sizes getting gradually smaller with coated film thickness in a direction away from the substrate.

14. The pattern layer as claimed in claim 13, wherein the pattern layer has lateral etch rate that gets smaller with the sizes of the crystal grains getting larger.

15. The pattern layer as claimed in claim 14, wherein the pattern layer has a side surface having a predetermined curvature.

16. The pattern layer as claimed in claim 15, wherein the predetermined curvature is in a range of 30-40 degree.
